(19) United States
(12) Patent Application Publication
(10) Pub. No.: US 2024/0218497 A1
(43) Pub. Date: Jul. 4, 2024

(54) METHOD OF PREPARING A COATING HAVING SELF-CLEANING AND ANTI-FOGGING PROPERTIES

(71) Applicant: NANYANG TECHNOLOGICAL UNIVERSITY, Singapore (SG)

(72) Inventors: Zhong CHEN, Singapore (SG); Rajdeep Singh RAWAT, Singapore (SG); Ye SUN, Singapore (SG)

(21) Appl. No.: 18/685,824

(22) PCT Filed: Jul. 28, 2022
(86) PCT No.: PCT/SG2022/050538

§ 371 Date: Feb. 22, 2024

(30) Foreign Application Priority Data
Aug. 19, 2021 (SG) 10202109064S

(51) Int. Cl. C23C 14/28; C23C 14/02; C23C 14/08; C23C 14/10

(52) U.S. Cl. CPC C23C 14/28; C23C 14/022; C23C 14/083; C23C 14/10

(57) ABSTRACT

A method of preparing a coating having self-cleaning and anti-fogging properties is provided. The method may include providing a polymeric substrate having an oxygen plasma-treated surface; depositing silicon dioxide directly on the oxygen plasma-treated surface of the polymeric substrate by pulsed laser deposition to form a silicon dioxide layer; and depositing titanium dioxide directly on the silicon dioxide layer by pulsed laser deposition to form a titanium dioxide layer as an outermost layer of the coating. A coating having self-cleaning and anti-fogging properties, uses of the coating and an article of manufacture comprising the coating are also provided.

### CROSS-REFERENCE TO RELATED APPLICATION

This application claims the benefit of priority of Singapore patent application number 10202109064S, filed 19 Aug. 2021, the content of which is incorporated herein by reference in its entirety for all purposes.

### TECHNICAL FIELD

Various embodiments relate to a method of preparing a coating having self-cleaning and anti-fogging properties, a coating having self-cleaning and anti-fogging properties, uses of the coating and an article of manufacture comprising the coating.

### BACKGROUND

Since discovery of light-induced super-amphiphilic activity of titanium dioxide (TiO₂) surfaces, much efforts have been devoted to explore use of this light induced wetting transformation. Light induced degradation of low energy hydrocarbon groups, as well as formation of high energy hydroxyl groups on titanium dioxide (TiO₂) surfaces, provide a wide range of possible applications such as self-cleaning and anti-fogging.

While much research has been carried out to prepare self-cleaning, anti-fogging TiO₂ coating on glass substrates, the same extent was not carried out on plastic lenses. Even though plastic lenses are more robust against mechanical impact damage, they are inferior in hardness, thus more vulnerable to mechanical abrasion and scratch. A top coat on plastic substrates may be used to improve mechanical robustness of the plastic substrates for a wide range of applications.

Sol-gel process is typically used to prepare coatings on plastic substrates. It allows a wide range of formulations to be deposited on the substrate under ambient conditions. After gelation, the coatings may be consolidated without heating or with low-temperature heating, thereby rendering the sol-gel process suitable for polymeric materials as they tend to be heat sensitive. However, long processing time and weak adhesion between film and substrate are barriers that need to be addressed.

In view of the above, there remains a need for an improved method of preparing a coating having self-cleaning and anti-fogging properties that overcomes or at least alleviates one or more of the above-mentioned problems.

### SUMMARY

In a first aspect, a method of preparing a coating having self-cleaning and anti-fogging properties is provided. The method comprises providing a polymeric substrate having an oxygen plasma-treated surface; depositing silicon dioxide directly on the oxygen plasma-treated surface of the polymeric substrate by pulsed laser deposition to form a silicon dioxide layer; and depositing titanium dioxide directly on the silicon dioxide layer by pulsed laser deposition to form a titanium dioxide layer as an outermost layer of the coating.

In a second aspect, a coating having self-cleaning and anti-fogging properties prepared by a method according to the first aspect is provided.

In a third aspect, a coating having self-cleaning and anti-fogging properties is provided. The coating comprises a polymeric substrate having an oxygen plasma-treated surface; a silicon dioxide layer disposed directly on the oxygen plasma-treated surface of the polymeric substrate; and a titanium dioxide layer disposed directly on the silicon dioxide layer, wherein the titanium dioxide layer forms an outermost layer of the coating.

In a fourth aspect, use of a coating prepared by a method according to the first aspect or according to the third aspect in anti-fouling coatings, self-cleaning surfaces, primer layer for surfaces, optical components, sensors, lens, goggles, mirrors, windshields, face shields, displays, windows, or cookware covers is provided.

In a fifth aspect, an article of manufacture comprising a coating prepared by a method according to the first aspect or according to the third aspect, wherein the article is an optical component, sensor, lens, goggles, mirror, windshield, face shield, display, window, or cookware covers is provided.

### BRIEF DESCRIPTION OF THE DRAWINGS

In the drawings, like reference characters generally refer to the same parts throughout the different views. The drawings are not necessarily drawn to scale, emphasis instead generally being placed upon illustrating the principles of various embodiments. In the following description, various embodiments of the invention are described with reference to the following drawings.

FIG. 1A shows field emission scanning electron microscope (FESEM) image of TiO₂ film deposited for 5 min (S1). Insert of FIG. 1A shows water contact angle (WCA) measurement of TiO₂ film deposited for 5 min (S1).

FIG. 1B shows atomic force microscopy (AFM) surface morphology of TiO₂ film deposited for 5 min (S1).

FIG. 1C shows FESEM image of TiO₂ film deposited for 10 min (S2). Insert of FIG. 1C shows WCA measurement of TiO₂ film deposited for 10 min (S2).

FIG. 1D shows atomic force microscopy (AFM) surface morphology of TiO₂ film deposited for 10 min (S2).

FIG. 1E shows FESEM image of TiO₂ film deposited for 30 min (S3). Insert of FIG. 1E shows WCA measurement of TiO₂ film deposited for 30 min (S3).

FIG. 1F shows AFM surface morphology of TiO₂ film deposited for 30 min (S3).

FIG. 2A shows optical transmittance between wavelength 400 nm to 700 nm of S1, S2 and S3 at the normal incident angle. Optical transmittance of pristine polycarbonate (PC) is also shown for comparison purposes.

FIG. 2B shows optical transmittance between wavelength 400 nm to 700 nm of S4 and S5 at the normal incident angle. Optical transmittance of pristine PC is also shown for comparison purposes.

FIG. 3A shows FESEM image of SiO₂/TiO₂ deposited for 1 hr/10 min (S4). Insert of FIG. 3A shows WCA measurement of SiO₂/TiO₂ deposited for 1 hr/10 min (S4).

FIG. 3B shows AFM surface morphology and deposited film thickness of SiO₂/TiO₂ deposited for 1 hr/10 min (S4).

FIG. 3C shows FESEM image of SiO₂/TiO₂ deposited for 30 min/10 min (S5). Insert of FIG. 3C shows WCA measurement of SiO₂/TiO₂ deposited for 30 min/10 min (S5).

FIG. 3D shows AFM surface morphology and deposited film thickness of SiO₂/TiO₂ deposited for 30 min/10 min (S5).

FIG. 4A shows step profile of deposited film S1 measured using AFM.

FIG. 4B shows step profile of deposited film S2 measured using AFM.

FIG. 4C shows step profile of deposited film S3 measured using AFM.

FIG. 4D shows step profile of deposited film S4 measured using AFM.

FIG. 4E shows step profile of deposited film S5 measured using AFM.

FIG. 5A is an optical image of water droplet of 5 μL on surface of S5 just before the droplet touches the surface (time=0 ms).

FIG. 5B is an optical image of water droplet of 5 μL on surface of S5 at time=93 ms, to depict spreading behaviour of water within 100 ms.

FIG. 5C is a digital image exhibiting antifogging performance of the coated (top) and uncoated (bottom) PC exposed to hot steam.

FIG. 6A shows survey X-ray photoelectron spectroscopy (XPS) spectra comparison between untreated, oxygen plasma surface treated polycarbonate, TiO₂ nanoparticle films (S2), and SiO₂/TiO₂ nanoparticle films (S4).

FIG. 6B is high resolution fitted XPS spectra of C 1s of SiO₂/TiO₂ films (S4).

FIG. 6C is high resolution fitted XPS spectra of O 1s of SiO₂/TiO₂ films (S4).

FIG. 6D is high resolution fitted XPS spectra of Si 2p of SiO₂/TiO₂ films (S4).

FIG. 6E is high resolution fitted XPS spectra of Ti 2p of SiO₂/TiO₂ films (S4).

FIG. 7A shows Fourier-transform infrared spectroscopy (FTIR) spectra of as-prepared SiO₂/TiO₂ nanoparticle films.

FIG. 7B shows X-ray powder diffraction (XRD) spectra of as-prepared SiO₂/TiO₂ nanoparticle films.

FIG. 8A shows methylene blue (MB) concentration (Cₜ/C₀) after 24 hr UV illumination for 4 test conditions: MB only, pristine PC without coating (“Pristine PC 24 hr”), SiO₂ coating (“SiO2 24 hr”), and SiO₂/TiO₂ coating (SiO2/TiO2 24 hr”, S5). The relative concentration is 0.88±0.02, 0.77±0.03, 0.77±0.02, and 0.64±0.02, respectively.

FIG. 8B shows absorption spectra of methylene blue solution for as-prepared S5 sample at initial, 5 hr and 24 hr irradiation time.

FIG. 8C shows water contact angle change with UV radiation time on SiO₂/TiO₂ surface (S5) deposited with oleic acid.

FIG. 9A shows FESEM observation of S5 sample after abrasion, as part of mechanical and durability tests of as-prepared SiO₂/TiO₂ nanoparticle films on PC substrate. Inset is the as-prepared surface before testing.

FIG. 9B shows FESEM observation of S5 sample after tape adhesion and peeling, as part of mechanical and durability tests of as-prepared SiO₂/TiO₂ nanoparticle films on PC substrate.

FIG. 9C shows optical transmittance after the abrasion and tape adhesion tests, as part of mechanical and durability tests of as-prepared SiO₂/TiO₂ nanoparticle films on PC substrate.

FIG. 9D shows FESEM image of sample after the crosshatch test, as part of mechanical and durability tests of as-prepared SiO₂/TiO₂ nanoparticle films on PC substrate.

### DESCRIPTION

The following detailed description refers to the accompanying drawings that show, by way of illustration, specific details and embodiments in which the invention may be practised. These embodiments are described in sufficient detail to enable those skilled in the art to practise the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Polymeric materials have been used as substitutes for glass in various applications such as display as they are low-cost, light-weight, and capable of being highly transparent. A top coating on polymeric substrates is usually required to improve mechanical robustness of the polymeric substrates. Development of such coatings, along with self-cleaning and anti-fogging properties, is important to extend use of the polymeric materials in application areas such as multifunctional antifogging lenses and displays.

With the above in mind, various embodiments refer in a first aspect to a method of preparing a coating having self-cleaning and anti-fogging properties.

As used herein, the term “self-cleaning” refers to inherent ability of a surface to keep clean over time, in the absence of, or with reduced need to apply, mechanical forces or chemicals such as detergents to the surface to remove foreign matter such as dirt. The term “anti-fogging”, on the other hand, refers to ability of a surface to prevent loss or reduction in visibility through the surface.

Advantageously, coatings according to embodiments disclosed herein are capable of exhibiting self-cleaning and anti-fogging properties. Without wishing to be bound by theory, this may be due to the coatings being superhydrophilic. As such, coatings disclosed herein may be able to attract moisture from the atmosphere and create a thin water layer on the polymeric substrate. The thin water layer may be uniform across surface of the substrate, thereby providing improved transparency and light transmissibility, and in turn better visibility to a user. Fogging of the polymeric substrate may also be prevented through use of the coatings. Furthermore, the coatings disclosed herein may be able to keep surfaces cleaner for a longer period of time, since foreign matter such as dirt and particles may be more easily removed. In applications such as coating on exterior surfaces or facades of buildings, self-cleaning of the building facades may take place during rain.

It has also been surprisingly found by the inventors that ultraviolet light irradiation and/or photocatalytic activation are not required to activate or maintain superhydrophilicity of the coatings disclosed herein. This distinguishes from state of the art coatings containing titanium oxide where photocatalytic activation or UV excitation is required. This further enhances practicability of surfaces functionalised with the coatings, since they may be used in low-light conditions, such as indoors or at night.

The method of preparing a coating having self-cleaning and anti-fogging properties may include providing a polymeric substrate having an oxygen plasma-treated surface. Advantageously, action of oxygen plasma on the polymeric substrate may result in generation of oxygen bonding on the surface. This increases surface energy of the polymer substrate, and may be used to enhance adhesion with subsequently deposited coatings.

In various embodiments, providing a polymeric substrate having an oxygen plasma-treated surface comprises treating a surface of the polymeric substrate with an oxygen-containing plasma.

Treating the surface of the polymeric substrate with an oxygen-containing plasma may be carried out for any suitable time depending, for example, on the flow rate and/or type oxygen-containing plasma used, as well as area to be treated. In various embodiments, treating a surface of the polymeric substrate with an oxygen-containing plasma may be carried out for a time period in the range from about 8 minutes to about 12 minutes, such as about 9 minutes to about 12 minutes, about 10 minutes to about 12 minutes, about 8 minutes to about 11 minutes, about 8 minutes to about 10 minutes, or about 9 minutes to about 11 minutes.

Treating a surface of the polymeric substrate with an oxygen-containing plasma may be carried out at a pressure in the range from about 10⁻³ mbar to about 10⁻¹ mbar, such as about 10⁻³ mbar to about 10⁻² mbar or about 10⁻² mbar to about 10⁻¹ mbar. In some embodiments, treating a surface of the polymeric substrate with an oxygen-containing plasma is carried out at a pressure in the range from about 10⁻³ mbar to about 10⁻² mbar.

Methods disclosed herein may include depositing silicon dioxide directly on the oxygen plasma-treated surface of the polymeric substrate by pulsed laser deposition to form a silicon dioxide layer; and depositing titanium dioxide directly on the silicon dioxide layer by pulsed laser deposition to form a titanium dioxide layer as an outermost layer of the coating. By the term “directly”, this means that the silicon dioxide layer is in contact with the oxygen plasma-treated surface of the polymeric substrate, while the titanium dioxide layer is in contact with the silicon dioxide layer. By virtue of the titanium dioxide layer being the outermost layer, this also means that there are only two layers—one of silicon dioxide and one of titanium dioxide on the polymeric substrate. Advantageously, despite the coating being formed of the two layers of silicon dioxide and titanium dioxide only, the coating is able to exhibit self-cleaning and anti-fogging properties, which renders the method suitable to be widely adopted in industry.

For depositing silicon dioxide directly on the oxygen plasma-treated surface of the polymeric substrate, targets containing silicon or silicon dioxide may be used.

In some embodiments, a silicon target is used. Accordingly, depositing silicon dioxide directly on the oxygen plasma-treated surface of the polymeric substrate may comprise providing a silicon target, and directing a pulsed laser beam at the silicon target in the presence of oxygen to generate silicon plasma which interacts with the background oxygen plasma to form the silicon dioxide layer on the polymeric substrate. The background oxygen plasma may be oxygen plasma that is generated due to action of pulsed laser beam on the oxygen that is present, and/or due to interaction of ablated silicon plasma with the oxygen that is present. For interaction of ablated silicon plasma with the oxygen that is present, collision and charge exchange between the ablated energetic silicon plasma species and background oxygen may create oxygen plasma and active oxygen species which interact with silicon plasma to form oxides of silicon.

In some embodiments, a silicon dioxide target is used. Accordingly, depositing silicon dioxide directly on the oxygen plasma-treated surface of the polymeric substrate may comprise providing a silicon dioxide target, and directing a pulsed laser beam at the silicon dioxide target to form the silicon dioxide layer on the polymeric substrate.

Likewise, for depositing titanium dioxide directly on the silicon dioxide layer, targets containing titanium or titanium dioxide may be used.

In some embodiments, a titanium target is used. Accordingly, depositing titanium dioxide directly on the silicon dioxide layer may comprise providing a titanium target, and directing a pulsed laser beam at the titanium target in the presence of oxygen to generate titanium plasma which interacts with the background oxygen plasma to form the titanium dioxide layer.

In some embodiments, a titanium dioxide target is used. Accordingly, depositing titanium dioxide directly on the silicon dioxide layer may comprise providing a titanium dioxide target, and directing a pulsed laser beam at the titanium dioxide target in the presence of oxygen to form the titanium dioxide layer.

Oxygen may not be required when a silicon dioxide target or a titanium oxide target is used, as pulsed laser deposition may reproduce stoichiometry of the target on the polymeric substrate. The respective process may nevertheless be carried out in the presence of oxygen, however, so as to prevent or avoid oxygen deficiencies in the silicon dioxide layer or titanium oxide layer that is being formed. Accordingly, in various embodiments, depositing silicon dioxide directly on the oxygen plasma-treated surface of the polymeric substrate and/or depositing titanium dioxide directly on the silicon dioxide layer may be carried out in the presence of oxygen, regardless of whether silicon or silicon dioxide, or titanium or titanium dioxide are being used as targets to form the respective layers.

In some embodiments, depositing of the silicon dioxide and the titanium dioxide may be carried out in a chamber in the presence of oxygen, and the oxygen may be introduced to the chamber at a flow rate in the range from about 100 sccm to about 300 sccm, about 120 sccm to about 300 sccm, about 150 sccm to about 300 sccm, about 200 sccm to about 300 sccm, about 250 sccm to about 300 sccm, about 100 sccm to about 250 sccm, about 100 sccm to about 200 sccm, about 150 sccm to about 250 sccm, or about 180 sccm to about 220 sccm.

The respective targets of silicon, silicon dioxide, titanium, and/or titanium dioxide may be independently spaced apart from the polymeric substrate at a distance in the range from about 3 cm to about 8 cm, such as about 5 cm to about 8 cm, about 6 cm to about 8 cm, about 3 cm to about 7 cm, about 3 cm to about 5 cm, about 4 cm to about 7 cm, or about 4 cm to about 6 cm. By the term “independently spaced apart”, this means that the respective targets may be spaced at the same or at a different distance away from the polymeric substrate.

In some embodiments, targets of silicon and titanium dioxide are used to form the respective silicon dioxide and titanium dioxide layers. The targets of silicon and titanium dioxide may be spaced apart from the polymeric substrate at a distance of about 4 cm to about 6 cm, such as about 5 cm.

In applying pulsed laser to the respective targets to sequentially deposit the silicon dioxide and titanium dioxide layers, high energy hydroxyl groups may be present on the formed layers. Furthermore, the silicon dioxide and titanium dioxide may be deposited in the form of nanoparticles, which may coalesce upon further application of the pulsed laser to result in formation of porous layers. Advantageously, these may result in good hydrophilicity and antifogging performance of the resultant coating.

The pulsed laser beam may form a spot size of about 3×10⁻⁴ cm² to about 7×10⁻⁴ cm² on the respective targets of silicon, silicon dioxide, titanium, and/or titanium dioxide. In various embodiments, the pulsed laser beam may form a spot size of about 4×10⁻⁴ cm² to about 7×10⁻⁴ cm², about 5×10⁻⁴ cm² to about 7×10⁻⁴ cm², about 6×10⁻⁴ cm² to about 7×10⁻⁴ cm², about 4×10⁻⁴ cm² to about 6×10⁻⁴ cm² or about 5×10⁻⁴ cm² to about 6×10⁻⁴ cm² on the respective targets. In specific embodiments, pulsed laser beam may form a spot size of about 4×10⁻⁴ cm² to about 6×10⁻⁴ cm² on the respective targets.

In various embodiments, the pulsed laser beam has a wavelength of about 532 nm.

In various embodiments, the pulsed laser beam has a frequency in the range from about 8 Hz to about 12 Hz, such as about 9 Hz to about 12 Hz, about 10 Hz to about 12 Hz, about 8 Hz to about 11 Hz, about 8 Hz to about 10 Hz, or about 9 Hz to about 11 Hz. In some embodiments, the pulsed laser beam has a frequency in the range from about 9 Hz to about 11 Hz.

The pulsed laser beam may have a fluence in the range from about 1 Jcm⁻² to about 10 Jcm⁻². For example, the pulsed laser beam may have a fluence in the range from about 2 Jcm⁻² to about 10 Jcm⁻², about 3 Jcm⁻² to about 10 Jcm⁻², about 4 Jcm⁻² to about 10 Jcm⁻², about 2 Jcm⁻² to about 8 Jcm⁻², about 2 Jcm⁻² to about 6 Jcm⁻², about 2 Jcm⁻² to about 5 Jcm⁻², about 3 Jcm⁻² to about 8 Jcm⁻², or about 4 Jcm⁻² to about 5 Jcm⁻². In some embodiments, the pulsed laser beam has a fluence in the range from about 4 Jcm⁻² to about 5 Jcm⁻².

Time period for depositing the silicon dioxide and the titanium dioxide may depend on thickness of the respective layers to be formed. In various embodiments, depositing the silicon dioxide is carried out for a time period in the range from about 20 minutes to about 70 minutes, such as about 20 minutes to about 70 minutes, about 30 minutes to about 70 minutes, about 20 minutes to about 50 minutes, about 20 minutes to about 40 minutes, or about 30 minutes. In some embodiments, depositing the silicon dioxide is carried out for a time period in the range from about 25 minutes to about 35 minutes.

Depositing the titanium oxide, on the other hand, may be carried out for a time period in the range from about 5 minutes to about 30 minutes, such as about 5 minutes to about 20 minutes, about 5 minutes to about 10 minutes, about 8 minutes to about 30 minutes, about 5 minutes to about 15 minutes, or about 10 minutes. In some embodiments, depositing the titanium dioxide is carried out for a time period in the range from about 8 minutes to about 12 minutes.

In specific embodiments, depositing the silicon dioxide and titanium dioxide are carried out for about 30 minutes and about 10 minutes, respectively.

Combined thickness of the silicon dioxide layer and the titanium dioxide layer may be less than 100 nm, for example, less than 90 nm, less than 80 nm, less than 60 nm or less than 50 nm. In some embodiments, combined thickness of the silicon dioxide layer and the titanium dioxide layer may be greater than 30 nm or 40 nm.

Depositing the silicon dioxide and the titanium dioxide may be carried out at any suitable pressure. In various embodiments, the depositing is carried out at a pressure of about 10⁻² mbar.

The polymeric substrate may be any suitable polymeric materials. Material for the polymeric substrate may, for example, be selected from the group consisting of polycarbonate, poly(methyl methacrylate), polyester, polyethylene terephthalate, polyimide, polytetrafluoroethylene, polypropylene, polyolefin, Nylon, silicone, polyvinyl chloride, polystyrene, and polyphenylene sulfide. Composites of these materials may also be used as the substrate.

In various embodiments the polymeric substrate is polycarbonate.

Shape and structure of the polymeric substrate may be arbitrarily selected, and is not limited to a planar surface. For example, the polymeric substrate may have a non-planar shape, or be in the form of a product or an article of manufacture having a surface onto which the coating is to be applied.

Various embodiments refer in a second aspect to a coating having self-cleaning and anti-fogging properties prepared by a method according to the first aspect, and in a third aspect to a coating having self-cleaning and anti-fogging properties. The coating may comprise a polymeric substrate having an oxygen plasma-treated surface; a silicon dioxide layer disposed directly on the oxygen plasma-treated surface of the polymeric substrate; and a titanium dioxide layer disposed directly on the silicon dioxide layer, wherein the titanium dioxide layer forms an outermost layer of the coating.

As mentioned above, combined thickness of the silicon dioxide layer and the titanium dioxide layer may be less than 100 nm, for example, less than 90 nm, less than 80 nm, less than 60 nm or less than 50 nm, and/or may be greater than 30 nm or 40 nm.

The silicon dioxide and titanium dioxide may be deposited in the form of nanoparticles. Either or both the silicon dioxide layer and the titanium dioxide layer may comprise or consist of nanoparticles having an average size in the range from about 10 nm to about 50 nm. The nanoparticles may, for example, have an average size in the range from about 20 nm to about 50 nm, about 30 nm to about 50 nm, about 10 nm to about 40 nm, about 10 nm to about 30 nm, or about 20 nm to about 40 nm.

The silicon dioxide and titanium dioxide nanoparticles may coalesce to form porous layers, whereby porosity of the layers may result in the coating have a certain surface roughness value. Surface roughness of the coating as measured on the titanium dioxide layer may, for example, be in the range from about 20 nm to about 60 nm, such as about 30 nm to about 60 nm, about 40 nm to about 60 nm, about 50 nm to about 60 nm, about 20 nm to about 50 nm, about 20 nm to about 40 nm, or about 30 nm to about 50 nm. Advantageously, these may result in good hydrophilicity or superhydrophilicity and antifogging performance of the resultant coating.

The silicon dioxide layer and the titanium dioxide layer may be crystalline, non-crystalline or a mixed phase of crystalline and non-crystalline. In various embodiments, the silicon dioxide layer and the titanium dioxide layer are non-crystalline.

Material for the polymeric substrate may be selected from the group consisting of polycarbonate, poly(methyl methacrylate), polyester, polyethylene terephthalate, polyimide, polytetrafluoroethylene, polypropylene, polyolefin, Nylon, silicone, polyvinyl chloride, polystyrene, and polyphenylene sulfide. Composites of these materials may also be used as the substrate. In specific embodiments, material for the polymeric substrate is polycarbonate.

The coating may be superhydrophilic in the absence of ultraviolet light irradiation. The term “superhydrophilic” as used herein refers to an attribute of a coating whereby contact angle between a water droplet and a surface of the coating is smaller than about 10°. For example, contact angle of the coating disclosed herein may be smaller than 10°, smaller than 8°, smaller than 5°, smaller than 4°, smaller than 3°, or smaller than 2°. Advantageously, as ultraviolet light irradiation is not required to activate superhydrophilicity of the coatings, this renders the coatings disclosed herein suitable for low-light use, such as indoor or night time uses.

Various embodiments refer in a further aspect to use of a coating disclosed herein or prepared by a method disclosed herein in anti-fouling coatings, self-cleaning surfaces, primer layer for surfaces, optical components, sensors, lens, goggles, mirrors, windshields, face shields, displays, windows, or cookware covers.

As the coating may be superhydrophilic, it is able to attract moisture, thereby creating a water layer that prevents fogging on plastic surfaces. The water layer may be a uniform water layer, which provides improved transparency and light transmissibility, and in turn better visibility to a user. Furthermore, the water layer may be able to keep surfaces cleaner for a longer period of time, since foreign matter such as dirt and particles may be removed more easily. Self-cleaning may be enhanced during rain, for example, if such coatings are applied to exterior of buildings.

Various embodiments refer in a further aspect to an article of manufacture comprising a coating disclosed herein or prepared by a method disclosed herein. The article may be an optical component, sensor, lens, goggles, mirror, windshield, face shield, display, window, or cookware covers.

In order that the invention may be readily understood and put into practical effect, particular embodiments will now be described by way of the following non-limiting examples.

### EXAMPLES

A facile and fast deposition technique for preparation of a transparent, self-cleaning, antifogging film on a polymeric or plastic substrate, such as a polycarbonate (PC), at room temperature with good mechanical durability according to embodiments disclosed herein is provided. Methods disclosed herein may be used to prepare a mechanically robust multi-functional antifogging coating on transparent plastic substrates.

The coating uses a thin double layered SiO₂/TiO₂ structure, which has an additional advantage of reduced visible light reflection. Briefly, the technique may involve two steps, which is developed for enhanced mechanical durability. The first step involves oxygen plasma surface treatment of a plastic, which may be carried out at room temperature, to enhance adhesion of the plastic surface with coatings. The second step uses pulse laser deposition (PLD) of silicon dioxide (SiO₂) and titanium dioxide (TiO₂) films to enable the desired multi-functionality. The oxygen plasma surface treatment may be carried out at room temperature.

The as-prepared nanostructured SiO₂/TiO₂ films demonstrate excellent anti-reflection and antifogging performance with self-cleaning capability. The oxygen plasma treatment changes the polymer surface chemistry to allow strong adhesion with the anti-fogging coatings. The SiO₂/TiO₂ coating exhibits superhydrophilicity even without the previously claimed necessary ultraviolet irradiation. The self-cleaning capability is demonstrated via photocatalytic degradation of methylene blue and oleic acid. Excellent adhesion of the coating to the substrate and mechanical robustness of the coating is exhibited by crosshatch and abrasion tests. The multifunctional coating on polymer substrates provides an avenue for practical applications for optical lenses and displays, and are promising for industrial applications for various optical components including lenses, displays, and face shields.

### 1. Experimental Details

1.1 Coating of SiO₂/TiO₂ Films on PC Substrate

The superhydrophilic SiO₂/TiO₂ coatings on polymeric substrates were prepared via a two-step process.

First, polymer lens material, polycarbonate (PC) (1.5 cm×1.5 cm) was cleaned with ethanol and deionized water for several cycles, before being dried at 50° C. The sample was then placed inside a radio frequency (RF) plasma reactor chamber made of a quartz tube with two capacitively coupled ring electrodes mounted externally on the quartz tube. The quartz tube was evacuated to a base pressure below 103 mbar. Oxygen gas was then introduced into the reactor chamber at a flow rate of 2 sccm, under which the chamber pressure was stabilized at 10⁻² mbar. Oxygen plasma was generated with 250 W RF power using a 13.56 MHz Caeser136 RF generator connected to the ring electrode through an auto-impedance matching unit. The plasma treatment was carried out for 10 min.

In the second step, oxygen plasma treated substrate was placed in a Pulsed Laser Deposition (PLD) chamber. Silicon (Si) and Titanium Dioxide (TiO₂) target (purchased from S1-Lab Pte Ltd, 99.99%) were placed at 5 cm away from the substrate. Nd:YAG 532 nm laser was operated at 10 Hz with laser pulse fluence of F=4.74 Jcm⁻². The laser beam was focused to a spot size≈5.0×10⁻⁴ cm² on the target surface. The PLD chamber was pumped down to 10⁻⁵ mbar. Oxygen was introduced into the chamber at the start of deposition at a flow rate of 200 sccm. The PLD chamber pressure was stabilized at 10⁻² mbar during deposition.

### 1.2 Material Characterization

The surface morphology was observed using a JEOL 7600 field emission scanning microscope (FESEM) operated at 2.0 kV. A NX10 Park system atomic force microscope (AFM) was used to examine the surface topology. A Perkin Elmer Frontier Fourier Transformation Infra-Red (FTIR) spectrometer was used to understand the surface chemical bonding. Kratos AXIS Supra X-ray Photoelectron Spectrometer (XPS) was applied for the surface chemical composition analysis. The binding energy of the C 1s peak from sp2-bonded carbon at 284.8 eV was used as a reference. Water contact angle (WCA) was recorded using a contact angle goniometer (OCA 20 Dataphysics) with 5 μL DI water droplet at room temperature. Light transmittance was measured by Perkin Elmer Lambda 950 UV-VIS-NIR spectrometer.

### 1.3 Photocatalytic Degradation Study

The ability for photocatalytic self-cleaning was investigated via decomposition of methylene blue solution under ambient condition (25° C.). The coated sample (area at 1.5×1.5 cm²) was placed in a petri dish containing 20 ml of aqueous methylene blue solution with the concentration of 15 μmol/L. The sample was left in dark without ultraviolet (UV) illumination for 30 min to achieve adsorption equilibrium. A homemade UV-LED light source was used in the current work that emits a single wavelength at 365 nm. The light intensity was set at 15.2 mW/cm². UV-vis absorption spectra of methylene blue solution were recorded using the same Perkin Elmer Lambda 950 UV-VIS-NIR spectrometer. The solution concentration was reported based on the light absorption peak intensity change around 660 nm.

In addition to the methylene blue degradation, the photocatalytic activity was also examined by degradation of oleic acid on the coated surface under UV irradiation. In this case, the test sample was dipped into a 0.5 wt % oleic acid solution in heptane, naturally dried, and then placed under UV illumination. Water contact angle was measured at different time intervals as an indicator of the amount of oleic acid left on the surface.

### 1.4 Mechanical Durability Test

Durability test was carried out based on the MIL-C-48497 test standard, which involves an abrasion test and an adhesion test of the coating. The adhesion test uses a cellophane tape pressed onto the coating surface, which was then pulled off slowly at an angle of 45°. The abrasion test was carried out using a cheese cloth pad to rub the surface at a constant force (400 grams weight uniformly distributed onto 1.5×1.5 cm² size substrate, the corresponding pressure is 26.7 kPa). In addition, crosshatch test was also performed following the ASTM D3359 standard to evaluate the coating adhesion and quality.

### 2. Results and Discussion

2.1 TiO₂ and SiO₂/TiO₂ Thin Films on PC Substrates

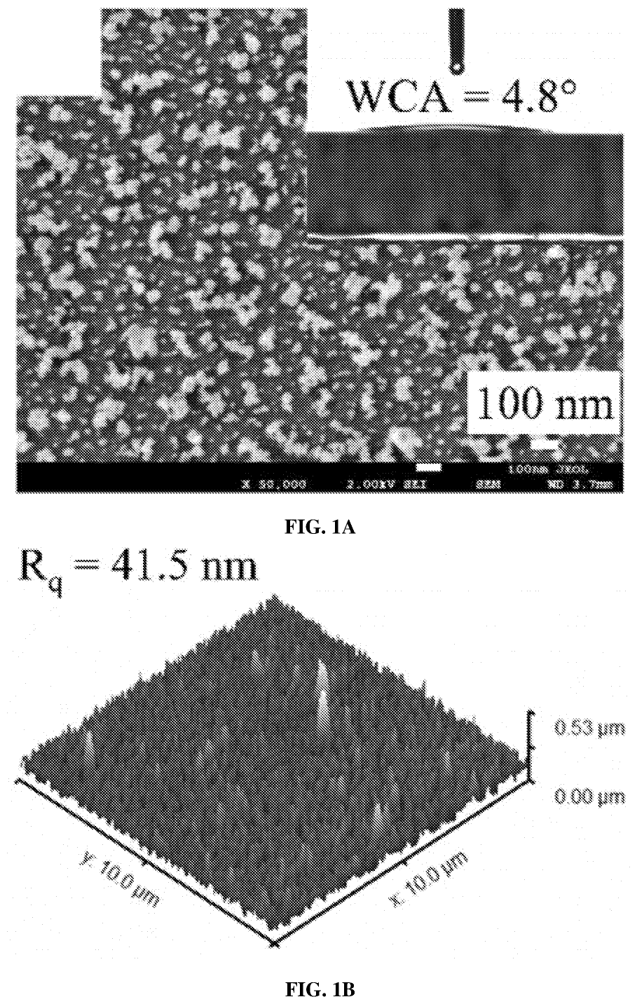

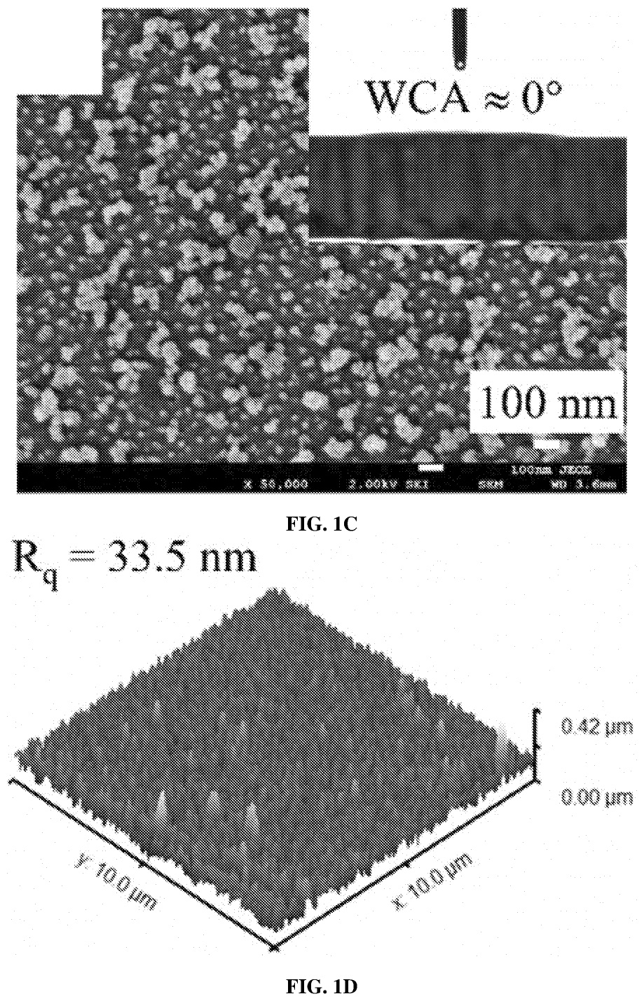

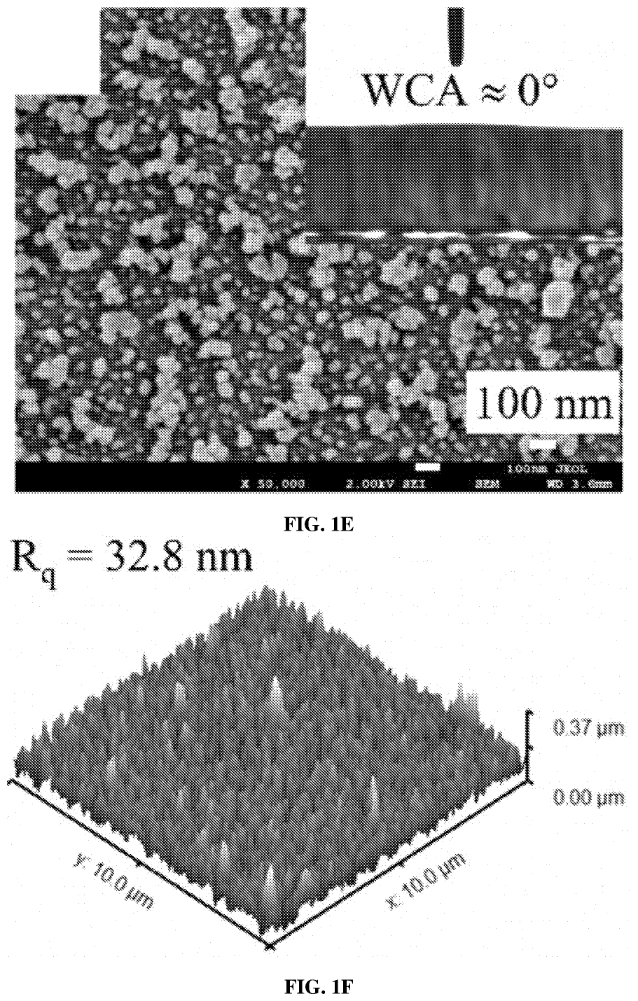

FIG. 1A to FIG. 1F present the surface morphology of as-prepared TiO₂ films at 5 min (S1), 10 min (S2), and 30 min (S3) deposition time, and the corresponding root-mean-square roughness (R_{q}) is around 41.5 nm, 33.5 nm, and 32.8 nm, respectively. The surface of the TiO₂ films were composed of nanoparticles with average size of 14.2±4.1 nm. With increase in deposition time, the deposited nanoparticles size does not change, and the morphology is similar while the nanoparticles aggregated into bigger clusters uniformly distributed on the surface. Surface roughness decreased from 41.5 nm to 32.8 nm, which suggests that more clusters are formed at longer deposition time resulting in reduction of the inter-cluster voids. Furthermore, the static water contact angle shown in FIG. 1C indicates that 10 min deposition of TiO₂ nanoparticle films has achieved complete wetting without UV irradiation or thermal treatment. The contact angle remained as low as around 15° after they were kept in dark for a week, displaying good stability of the coating.

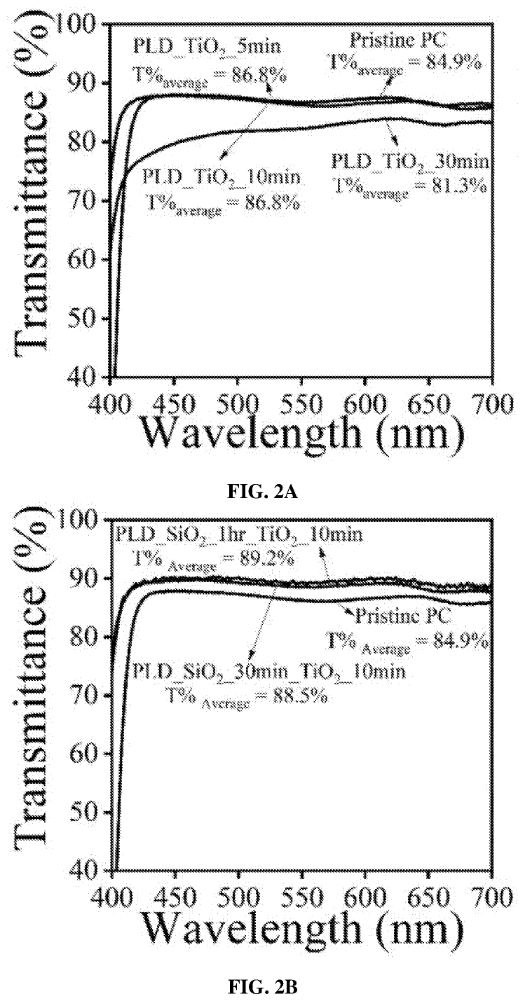

The S1 and S2 samples exhibited a slight increase in the visible light transmittance (average light transmittance between 400 nm to 700 nm is 86.8%) when compared with the pristine PC substrate (average light transmittance between 400 nm to 700 nm is 84.9%). This small amount of increase in light transmission (FIG. 2A) can be explained as the intrinsic property of TiO₂ material: the high absorption in the UV range results in the increase of transmittance around wavelength of 400 nm. For the S3 sample, significant reduction of light transmittance was observed (84.9% to 81.3%), which is due to the increase of light diffusion with the nanoparticle aggregation.

To achieve enhanced light transmission through the coating, the inventors added a layer of SiO₂ before the deposition of TiO₂ film. Since superhydrophilicity can be achieved by 10 min deposition of TiO₂, the inventors investigated two different conditions by adding a layer of SiO₂ deposited at 1 hr (S4) and 30 min (S5) deposition time.

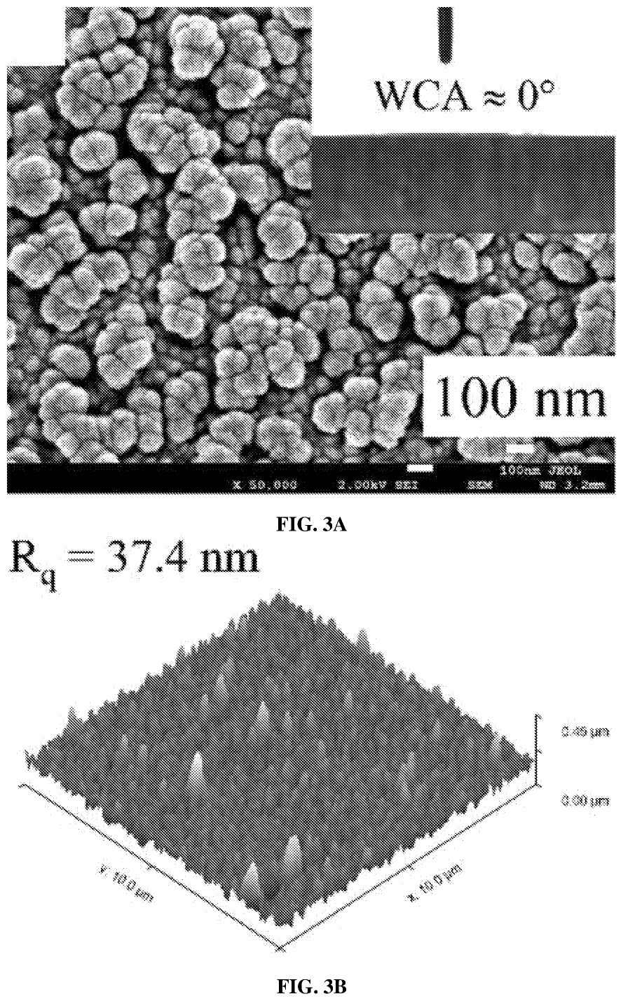

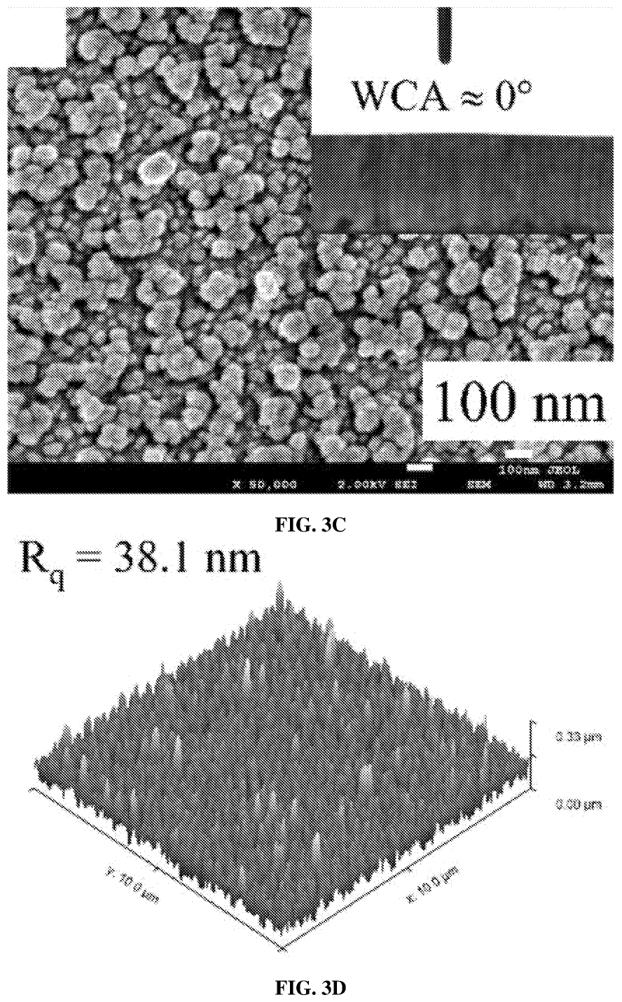

Morphology of the deposited films has changed as shown in FIG. 3A to FIG. 3D. Large nanoparticles with average size of 37.1±8.7 nm were observed for both S4 and S5. Nanoparticles aggregated into larger clusters uniformly distributed on the surface, and the surface roughness is very similar. Static WCA shows both samples exhibit superhydrophilicity with a complete wetting of water droplet. Furthermore, S4 and S5 demonstrates large increase in average light transmittance between 400 nm to 700 nm wavelength (S4 89.2%, S5 88.5%) shown in FIG. 2B. This suggests that SiO₂/TiO₂ nanoparticle films possess anti-reflection property. The as-prepared SiO₂/TiO₂ films can be recognized as a two-layered broadband anti-reflection coating. The best anti-reflection performance can be obtained by using a combination of the high refractive index material and low refractive index material with controlled thickness. The combination of SiO₂ and TiO₂ in this work represents low and high refractive index, respectively. S5 shows the best result in terms of average light transmittance as well as superhydrophilicity.

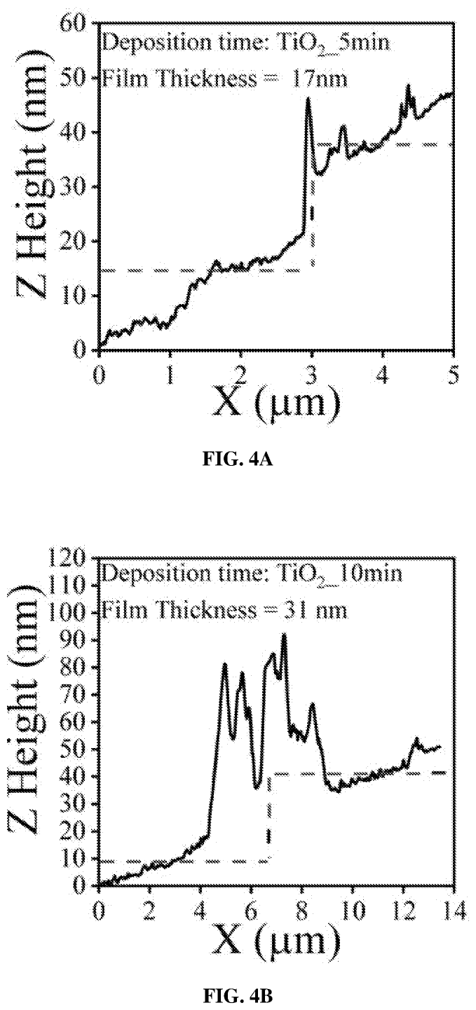

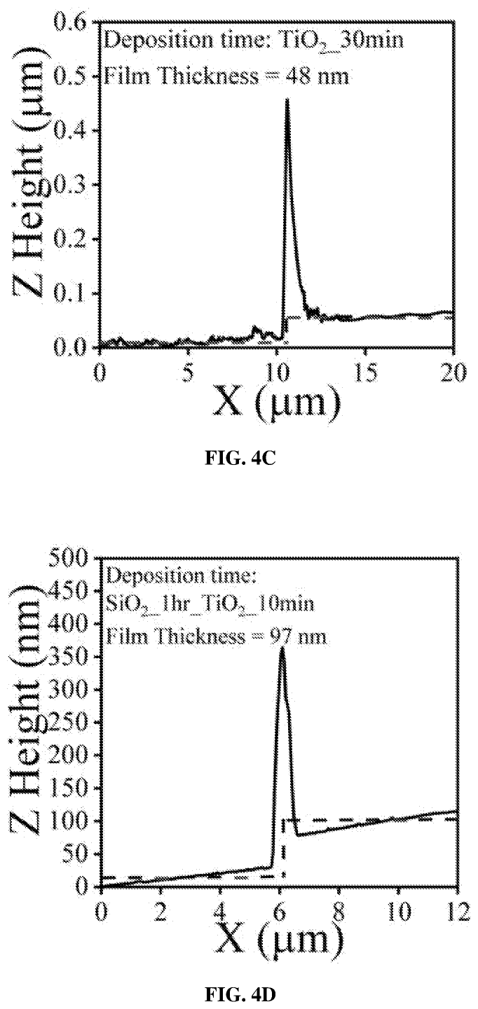

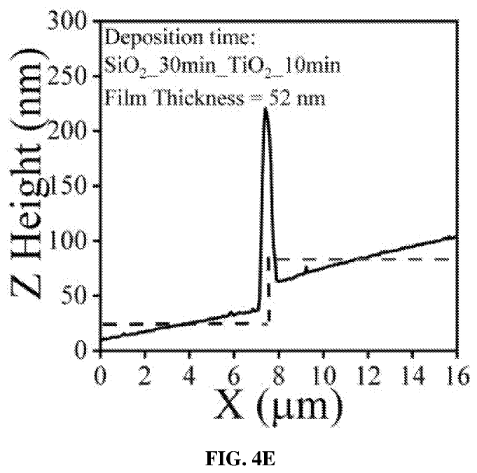

TABLE 1 summarizes the deposition details and film thickness, and provides summary of sample deposition details with data of the thickness and surface roughness of the deposited films (step profile measured with AFM technique shown in FIG. 4A to FIG. 4E).

TABLE 1

| | | | Surface |
|---|---|---|---|
| Sample | Deposition | Film thickness | roughness (R_{q}) |
| S1 | TiO₂ 5 min | 14.3 ± 2.4 nm | 41.5 nm |
| S2 | TiO₂ 10 min | 30.7 ± 6.1 nm | 33.5 nm |
| S3 | TiO₂ 30 min | 49.6 ± 1.3 nm | 32.8 nm |
| S4 | SiO₂ 1 hr + TiO₂ 10 min | 94.0 ± 4.5 nm | 37.4 nm |
| S5 | SiO₂ 30 min + TiO₂ 10 min | 60.1 ± 8.1 nm | 38.1 nm |

### 2.2 Antifogging Performance

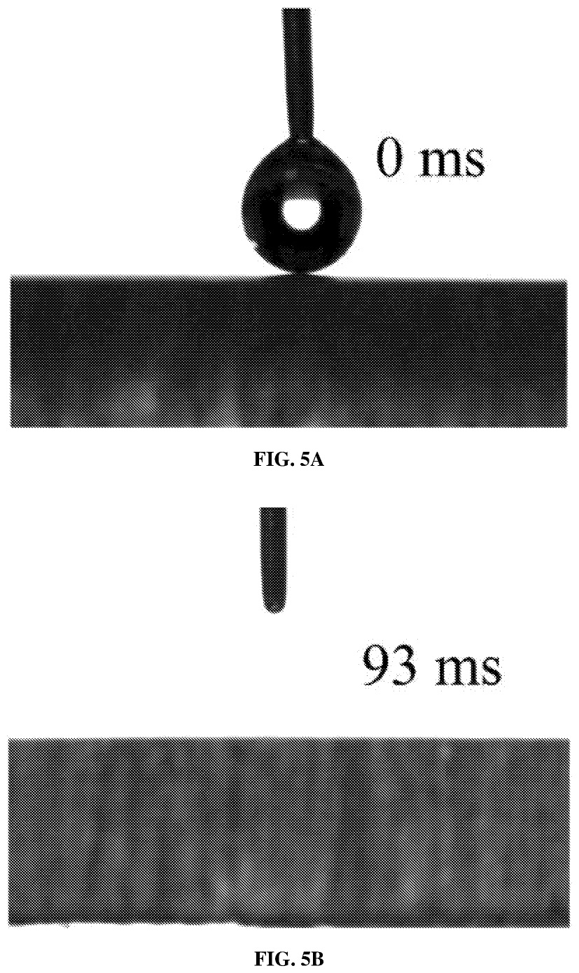

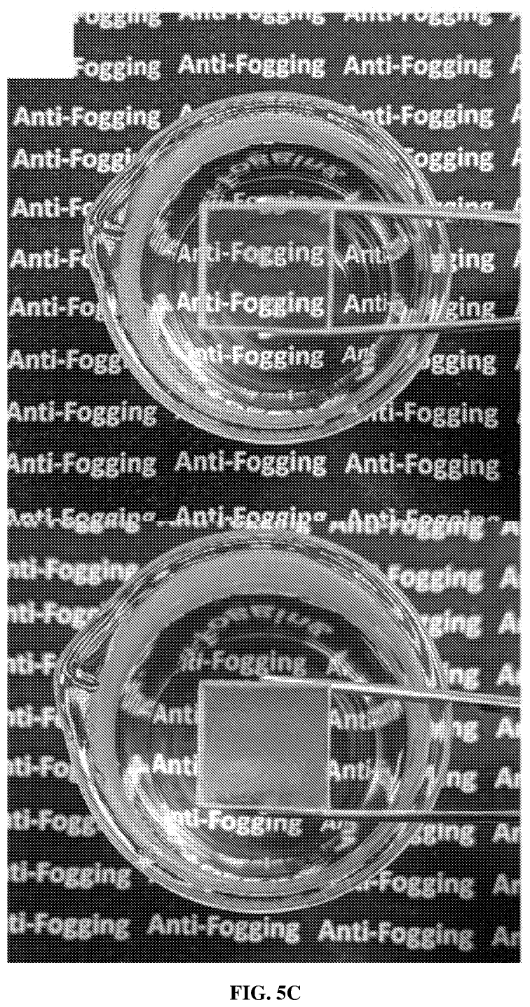

The spreading behaviour of water droplet on the as-prepared SiO₂/TiO₂ thin film shown in FIG. 5A and FIG. 5B provides an additional evidence for the excellent superhydrophilicity of the coating. Digital image taken at 0 and 93 ms indicates that the water droplet spreads rapidly within 100 ms.

FIG. 5C demonstrates the fogging test results under steam test. The uncoated PC fogged immediately upon exposure to water steam, whereas the as-prepared SiO₂/TiO₂ coated surface remained transparent, displaying its excellent antifogging performance.

### 2.3 Surface Chemical Analysis

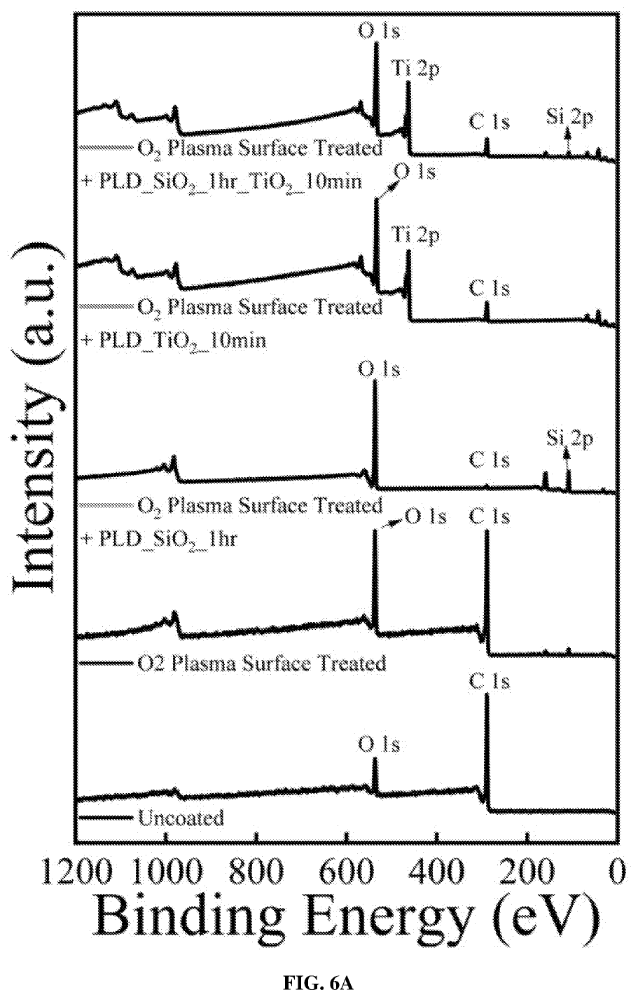

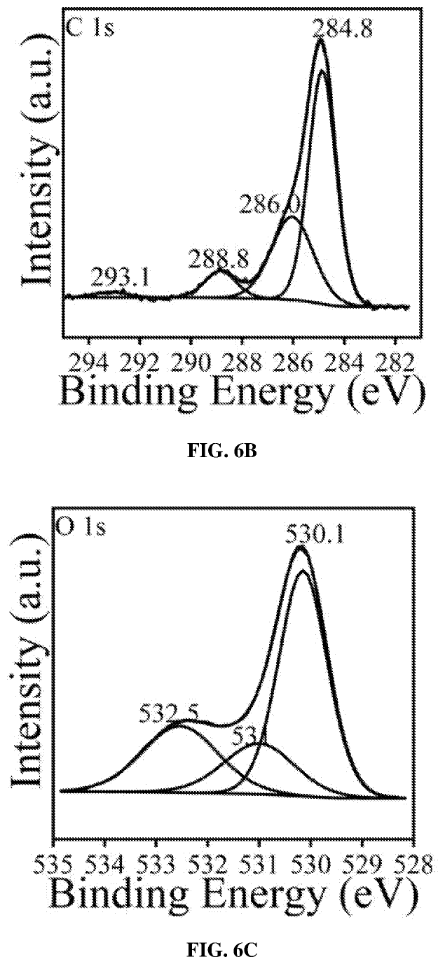

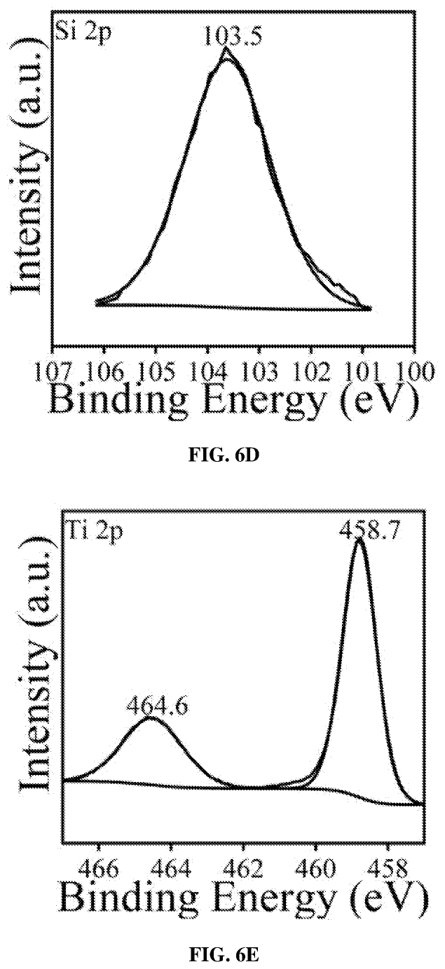

XPS analysis was conducted to understand the surface chemical composition of constituent elements. FIG. 6A shows the XPS survey spectra of untreated, oxygen plasma treated PC substrate, TiO₂ nanoparticle films (S2), and SiO₂/TiO₂ nanoparticle films (S4). A significant increase of surface oxygen peak after oxygen plasma treatment was observed. Abundant oxygen bonding on the surface created by oxygen plasma treatment increases the surface energy of the polymer substrate, which could enhance the adhesion with the subsequently deposited coatings. Both survey spectra of S2 and S4 clearly indicate coating consists of titanium (Ti), while additional silicon (Si) peaks can be observed. Doublet peaks of Ti 2p located at 458.7 eV and 464.6 eV shown in high resolution spectra

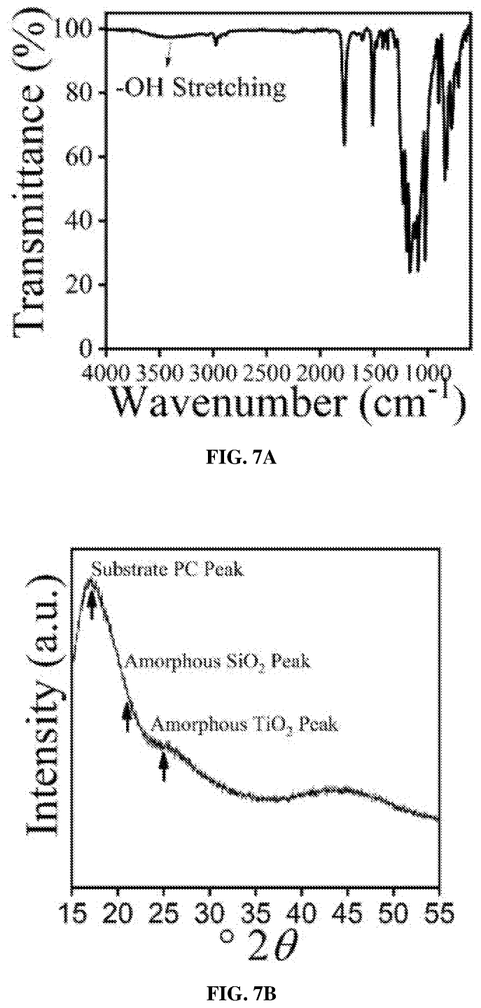

FIG. 6E further confirm the success deposition of TiO₂ on the surface. The O 1s peak at 532.5 eV and the Si 2p peak at 103.5 eV in high resolution spectra (FIG. 6C and FIG. 6D) of S4 film are characterized as Si—O—Si bond. Therefore, the presence of TiO₂ bond as well as SiO₂ bond shown in XPS result clearly indicates the successful deposition of bi-layered oxide film. Hydroxyl group (—OH) was identified by Fourier transform infra-red spectroscopy (FTIR) indicated in FIG. 7A in the range of 3000 cm⁻¹ to 3800 cm⁻¹. High energy hydroxyl group on the surface complemented with the porous structure of the as-prepared SiO₂/TiO₂ nanoparticles has resulted in the excellent hydrophilicity and antifogging performance. In addition, the broadened peak centered around 20 value of 20° to 25° in X-ray diffraction (XRD) pattern in FIG. 7B suggests that SiO₂/TiO₂ nanoparticle films was largely non-crystalline.

### 2.4 Photocatalytic Self-Cleaning

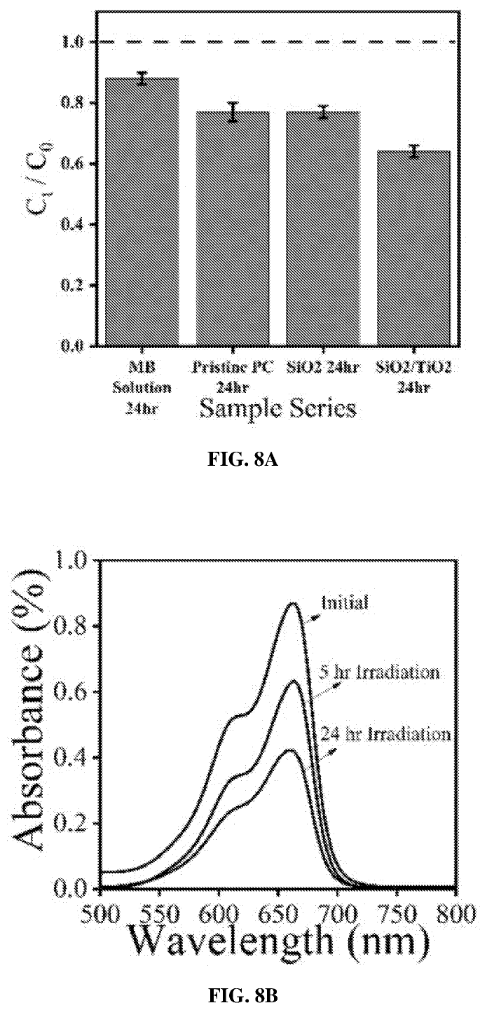

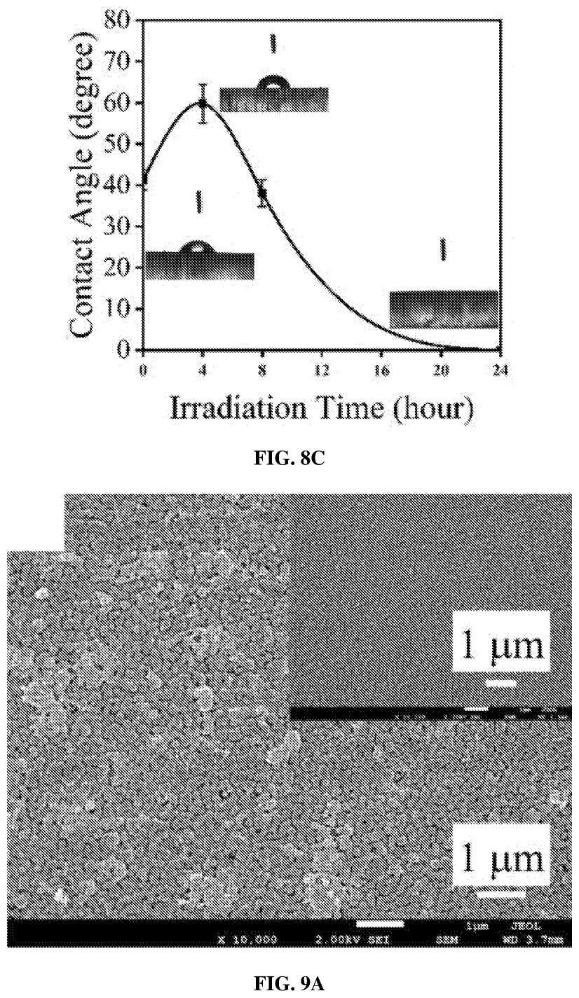

FIG. 8A displays normalized concentration (Cₜ/C₀) of the methylene blue (MB) solution after 24 hr UV illumination for three different samples: PC without coating (“Pristine PC 24 hr”), SiO₂ coating (“SiO2 24 hr”), and SiO₂/TiO₂ coating (SiO₂/TiO2 24 hr”, S5). MB solution without any sample was also exposed to the UV light for 24 hr.

There was an 11% decrease in the MB solution concentration caused by the hydrolysis under UV. For the uncoated PC and SiO₂ sample, the MB solution has dropped by 23%, due to hydrolysis and surface adsorption. The TiO₂ sample clearly displays its photocatalytic activity, as indicated a further 13% decrease compared with the uncoated PC and SiO₂ sample.

Degradation of oleic acid, as another model organic pollutant, on S5 sample surface was further investigated to verify its photocatalytic self-cleaning ability. The WCA was used as an indirect evidence of the surface concentration of this compound. Oleic acid is a fatty acid with a non-polar end, its presence leads to an increased contact angle. If the degradation does occur, the contact angle would recover to its original state. As shown in FIG. 8C, the WCA was 42° after oleic acid deposition, and it decreased slowly to nearly 0° (complete wetting) after 24 hr of UV irradiation. This confirms the photodegradation of oleic acid by TiO₂ on the surface.

### 2.5 Mechanical Robustness

Mechanical robustness and durability are the main considerations for practical applications. In this study, mechanical robustness of the coatings were evaluated by testing the adhesion as well as the abrasion based on US Military Standards (MIL-C-48497). This particular standard is the most appropriate specification for optical coatings. Since S5 sample exhibits the best result in terms of transparency and hydrophilicity, all the mechanical tests were performed using this sample.

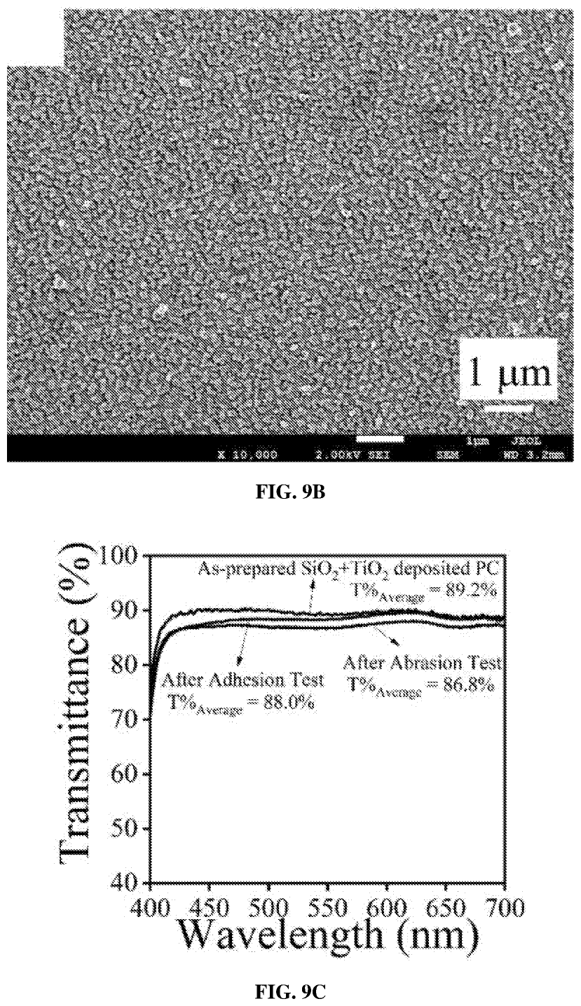

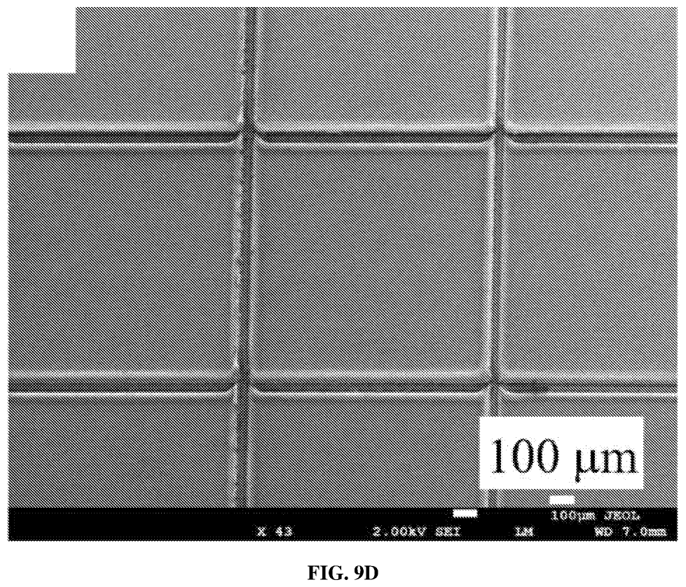

Observation by naked eyes as well as FESEM did not find any perceivable damage after the MIL-C-48497 abrasion and tape adhesion tests (cf. FIG. 9A and FIG. 9B). There was a minor change in the morphology contrast in FIG. 9A, due to the residues left on the surface after the cloth abrasion. Little surface roughness change was observed as R_{q} was around 35 nm after abrasion test (cf. 38.1 nm before abrasion). Surface after abrasion and adhesion test still has good transparency despite a slight drop of average light transmittance (FIG. 9C). The surface after abrasion and adhesion tests exhibited good water wettability and antifogging performance.

Further evaluation of film quality and adhesion with substrate was evaluated by the crosshatched test (ASTM D3359). The cutting edges were smooth, and no chipping was present along the crosshatched lines, showing a “clean” cut (FIG. 9D). The coating was graded as 5B, the best quality grade as described by the ASTM D3359 test standard. Combing both the MIL and ASTM tests, it may be concluded that the SiO₂/TiO₂ anti-fogging coating obtained possesses good adhesion strength and mechanical integrity.

### 3. Conclusion

The inventors have successfully fabricated superhydrophilic TiO₂ coating on a polycarbonate substrate with a prior plasma treatment. With an intermediate layer of SiO₂ between the top TiO₂ layer and the substrate, the composite film displayed excellent antifogging and anti-reflection properties. Due to the photocatalytic effect of TiO₂, the coating was also able to remove organic residues under UV irradiation. In addition, the coating displayed excellent mechanical resistance again cloth abrasion and tape peeling, and it also demonstrated good adhesion with the plastic substrate. With all these demonstrated multifunctionalities, the achieved coating has a great potential for industrial applications including plastic lenses, displays, and face shields.

By “comprising” it is meant including, but not limited to, whatever follows the word “comprising”. Thus, use of the term “comprising” indicates that the listed elements are required or mandatory, but that other elements are optional and may or may not be present.

By “consisting of” is meant including, and limited to, whatever follows the phrase “consisting of”. Thus, the phrase “consisting of” indicates that the listed elements are required or mandatory, and that no other elements may be present.

The inventions illustratively described herein may suitably be practiced in the absence of any element or elements, limitation or limitations, not specifically disclosed herein. Thus, for example, the terms “comprising”, “including”, “containing”, etc. shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the inventions embodied therein herein disclosed may be resorted to by those skilled in the art, and that such modifications and variations are considered to be within the scope of this invention.

By “about” in relation to a given numerical value, such as for temperature and period of time, it is meant to include numerical values within 10% of the specified value.

The invention has been described broadly and generically herein. Each of the narrower species and sub-generic groupings falling within the generic disclosure also form part of the invention. This includes the generic description of the invention with a proviso or negative limitation removing any subject matter from the genus, regardless of whether or not the excised material is specifically recited herein.

Other embodiments are within the following claims and non-limiting examples. In addition, where features or aspects of the invention are described in terms of Markush groups, those skilled in the art will recognize that the invention is also thereby described in terms of any individual member or subgroup of members of the Markush group.

1. A method of preparing a coating having self-cleaning and anti-fogging properties, the method comprising
providing a polymeric substrate having an oxygen plasma-treated surface;
depositing silicon dioxide directly on the oxygen plasma-treated surface of the polymeric substrate by pulsed laser deposition to form a silicon dioxide layer; and
depositing titanium dioxide directly on the silicon dioxide layer by pulsed laser deposition to form a titanium dioxide layer as an outermost layer of the coating.

2. The method according to claim 1, wherein providing a polymeric substrate having an oxygen plasma-treated surface comprises treating a surface of the polymeric substrate with an oxygen-containing plasma for a time period in the range from about 8 minutes to about 12 minutes.

3. (canceled)

4. The method according to claim 2, wherein treating a surface of the polymeric substrate with an oxygen-containing plasma is carried out at a pressure in the range from about 10⁻³ mbar to about 10⁻¹ mbar.

5. The method according to claim 1, wherein depositing silicon dioxide directly on the oxygen plasma-treated surface of the polymeric substrate comprises providing a silicon target, and directing a pulsed laser beam at the silicon target in the presence of oxygen to generate silicon plasma which interacts with the background oxygen plasma to form the silicon dioxide layer on the polymeric substrate.

6. The method according to claim 1, wherein depositing silicon dioxide directly on the oxygen plasma-treated surface of the polymeric substrate comprises providing a silicon dioxide target, and directing a pulsed laser beam at the silicon dioxide target to form the silicon dioxide layer on the polymeric substrate.

7. The method according to claim 1, wherein depositing titanium dioxide directly on the silicon dioxide layer comprises providing a titanium dioxide target, and directing a pulsed laser beam at the titanium dioxide target to form the titanium dioxide layer.

8. The method according to claim 1, wherein depositing titanium dioxide directly on the silicon dioxide layer comprises providing a titanium target, and directing a pulsed laser beam at the titanium target in the presence of oxygen to generate titanium plasma which interacts with the background oxygen plasma to form the titanium dioxide layer.

9. (canceled)

10. The method according to claim 1, wherein the pulsed laser deposition is carried using a pulsed laser beam has having a wavelength of about 532 nm, or a frequency in the range from about 8 Hz to about 12 Hz, or a fluence in the range from about 1 Jcm⁻² to about 10 Jcm⁻².

11.-14. (canceled)

15. The method according to claim 1, wherein depositing the silicon dioxide is carried out for a time period in the range from about 20 minutes to about 70 minutes.

16. The method according to claim 1, wherein depositing the titanium oxide is carried out for a time period in the range from about 5 minutes to about 30 minutes.

17.-18. (canceled)

19. The method according to claim 1, wherein combined thickness of the silicon dioxide layer and the titanium dioxide layer is less than 100 nm.

20. The method according to claim 1, wherein material for the polymeric substrate is selected from the group consisting of polycarbonate, poly(methyl methacrylate), polyester, polyethylene terephthalate, polyimide, polytetrafluoroethylene, polypropylene, polyolefin, Nylon, silicone, polyvinyl chloride, polystyrene, and polyphenylene sulfide.

21. A coating having self-cleaning and anti-fogging properties prepared by a method according to claim 1.

22. A coating having self-cleaning and anti-fogging properties, comprising
a polymeric substrate having an oxygen plasma-treated surface;
a silicon dioxide layer disposed directly on the oxygen plasma-treated surface of the polymeric substrate; and
a titanium dioxide layer disposed directly on the silicon dioxide layer, wherein the titanium dioxide layer forms an outermost layer of the coating.

23. The coating according to claim 22, wherein combined thickness of the silicon dioxide layer and the titanium dioxide layer is less than 100 nm.

24. The coating according to claim 22, wherein material for the polymeric substrate is selected from the group consisting of polycarbonate, poly(methyl methacrylate), polyester, polyethylene terephthalate, polyimide, polytetrafluoroethylene, polypropylene, polyolefin, Nylon, silicone, polyvinyl chloride, polystyrene, and polyphenylene sulfide.

25. The coating according to claim 22, wherein either or both the silicon dioxide layer and the titanium dioxide layer comprise or consist of nanoparticles having an average size in the range from about 10 nm to about 50 nm.

26. The coating according to claim 22, wherein surface roughness of the coating as measured on the titanium dioxide layer is in the range from about 20 nm to about 60 nm.

27. The coating according to claim 22, wherein the coating is superhydrophilic in the absence of ultraviolet light irradiation.

28. (canceled)

29. An article of manufacture comprising a coating having self-cleaning and anti-fogging properties,
(a) the coating prepared by a method comprising providing a polymeric substrate having an oxygen plasma-treated surface; depositing silicon dioxide directly on the oxygen plasma-treated surface of the polymeric substrate by pulsed laser deposition to form a silicon dioxide layer; and depositing titanium dioxide directly on the silicon dioxide layer by pulsed laser deposition to form a titanium dioxide layer as an outermost layer of the coating, or
(b) the coating comprising a polymeric substrate having an oxygen plasma-treated surface; a silicon dioxide layer disposed directly on the oxygen plasma-treated surface of the polymeric substrate; and a titanium dioxide layer disposed directly on the silicon dioxide layer, wherein the titanium dioxide layer forms an outermost layer of the coating,
wherein the article is an optical component, sensor, lens, goggles, mirror, windshield, face shield, display, window, or cookware covers.
